(19) United States
(12) Patent Application Publication
(10) Pub. No.: US 2016/0265103 A1
(43) Pub. Date: Sep. 15, 2016

(54) EAST CHINA UNIVERSITY OF SCIENCE AND TECHNOLOGY

(71) Applicant: EAST CHINA UNIVERSITY OF SCIENCE AND TECHNOLOGY, Shanghai (CN)

(72) Inventors: Chongjun ZHAO, Shanghai (CN); Jianbo DONG, Shanghai (CN); Xiangmao DONG, Shanghai (CN); Xiuzhen QIAN, Shanghai (CN)

(73) Assignee: EAST CHINA UNIVERSITY OF SCIENCE AND TECHNOLOGY, Shanghai (CN)

(21) Appl. No.: 15/030,580

(22) PCT Filed: Oct. 31, 2013
(86) PCT No.: PCT/CN2013/086317

§ 371 Date: Apr. 19, 2016

(51) Int. Cl. C23C 14/58; C01B 31/04

(52) U.S. Cl. CPC C23C 14/5813; C01B 31/0453; B82Y 40/00

(57) ABSTRACT

Methods described herein generally relate to producing patterned graphene. The method may include irradiating at least one focal point on a surface of a metal substrate with a laser beam in the presence of carbon dioxide, wherein the laser beam is generated by an ultra-short pulse laser; and causing the laser beam to move relative to the surface of the metal substrate such that the at least one focal point is displaced along a pattern on the surface, thereby producing a patterned graphene. Apparatuses for producing patterned graphene are also disclosed.

### BACKGROUND

Unless otherwise indicated herein, the materials described in this section are not prior art to the claims in this application and are not admitted to be prior art by inclusion in this section.

Graphene, an allotrope of carbon in the form of one atom thick sheets of carbon atoms, have a number of unique electrical and mechanical properties that make them attractive for use in a wide range of applications, including nanoelectronics, hydrogen storage, lithium-ion batteries, and antibacterial agents. However, difficulties with large scale production of high quality graphene and structuralization of graphene (for example, the direct application of graphene as a device) have limited the applications of graphene.

Although graphene films can be prepared by chemical vapor deposition methods or expitaxial growth methods, the resulting graphene is typically a film which may generally include non-uniform arrays of hexagonally arranged carbon atoms. The irregularities in the arrays of carbon atoms form grain boundaries which can weaken the mechanical properties of the film, thereby presenting challenges in patterning of these films to form patterned graphene.

### SUMMARY

Some embodiments disclosed herein relate to methods for producing a patterned graphene. The method can include irradiating at least one focal point on a surface of a metal substrate with a laser beam in the presence of carbon dioxide; and causing the laser beam to move relative to the surface of the metal substrate such that the at least one focal point is displaced along a pattern on the surface, thereby producing a patterned graphene. In some embodiments, the laser beam is generated by an ultra-short pulse laser. In some embodiments, the method further comprises isolating the patterned graphene.

Some embodiments disclosed herein relate to apparatuses for producing a patterned graphene. The apparatus, in some embodiments, can include an ultra-short pulse laser configured to produce a laser beam; and a housing configured to accommodate a metal substrate and carbon dioxide, wherein the housing can comprise an optical port configured to allow irradiation of at least one focal point on the surface of the metal substrate by the laser beam.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are not to be considered limiting of its scope, the disclosure will be described with additional specificity and detail through use of the accompanying drawings.

FIG. 1 is a schematic illustration of one non-limiting example of an apparatus for producing a patterned graphene in accordance with the disclosed embodiments.

FIG. 2 is a flow diagram illustrating one non-limiting example of a method of producing graphene in accordance with the disclosed embodiments.

FIGS. 3A and 3B are an optical microphotograph and a scanning electron microscopy (“SEM”) image, respectively, of graphene synthesized on the surface of a zinc sheet by scanning a laser in air. FIG. 3C is an optical microscope image of patterned graphene prepared according to Example 1. FIGS. 3D and 3E are SEM images (at 1.00 μm and 500 nm, respectively) of patterned graphene prepared according to Example 1.

FIGS. 4A and 4B are an optical microscope image and a SEM image, respectively, of graphene synthesized on the surface of an aluminum sheet by scanning the laser in air. FIG. 4C is an optical microscope image of patterned graphene prepared according to Example 2. FIGS. 4D and 4E are SEM images (at 5.00 μm and 500 nm, respectively) of patterned graphene prepared according to Example 2.

FIGS. 5A and 5B are an optical microscope image and a SEM image, respectively, of graphene synthesized on the surface of a magnesium sheet by scanning the laser in air. FIGS. 5C, 5D, and 5E are an optical microscope image, a SEM image (at 5.00 μm), and a transmission electron microscopy (“TEM”) image, respectively, of patterned graphene prepared according to Example 3.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated and make part of this disclosure.

The present disclosure generally relates to apparatuses and methods related to producing graphene by laser-induced carbon dioxide conversion. The produced graphene can be patterned. The disclosed apparatuses and methods can provide simple and rapid routes to producing graphene and to achieve conversion and in situ immobilization of carbon dioxide to form the graphene. The disclosed apparatus and methods may be used for large-scale, industrial production of graphene. For example, some embodiments of the present disclosure may provide for a simple and practical method and apparatus for the large scale production of graphene and for the production of designable, patterned graphene. Some embodiments of the present disclosure may also provide for a method to effectively capture and immobilize carbon dioxide to convert the carbon dioxide to graphene.

### Apparatus for Producing a Patterned Graphene

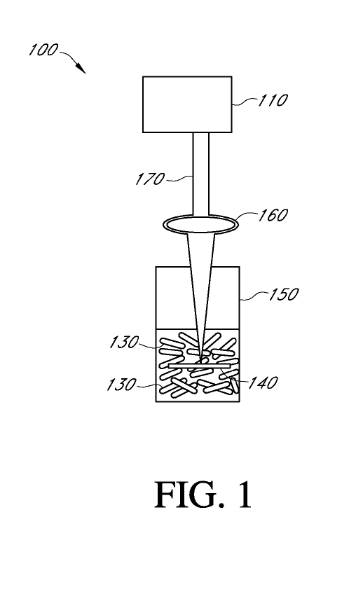

Some embodiments disclosed herein relate to apparatuses for producing a patterned graphene. FIG. 1 is a schematic illustration of one non-limiting example of the apparatus. As shown in FIG. 1, apparatus 100 can include an ultra-short pulse laser 110 configured to produce a laser beam 170, and a housing 150 configured to accommodate carbon dioxide 130 and a metal substrate 140.

In some embodiments, the ultra-short pulse laser 110 can include attosecond lasers, femtosecond lasers, excimer lasers, nanolasers, or a combination thereof.

The ultra-short pulse laser may produce a laser beam 170. The power at which the utltra-short pulse laser operates can vary, for example, at about 0.001 mW/pulse to about 250 mW/pulse. In some embodiments, the ultra-short pulse laser may operate at a power of about 0.01 mW/pulse to about 150 mW/pulse, about 0.5 mW/pulse to about 100 mW/pulse, about 1 mW/pulse to about 75 mW/pulse, or a value within any of these ranges (including endpoints). In some embodiments, the laser beam ultra-short pulse laser may operate at a power of at least about 0.001 mW/pulse, at least about 0.1 mW/pulse, at least about 0.5 mW/pulse, at least about 0.8 mW/pulse, at least about 1 mW/pulse, or a power between any of these values. In some embodiments, the laser beam ultra-short pulse laser may operate at a power of less than about 150 mW/pulse, less than about 140 mW/pulse, less than about 130 mW/pulse, less than about 120 mW/pulse, less than about 110 mW/pulse, or a power between any of these values. In some embodiments, the ultra-short pulse laser may operate at a power of about 0.5 mW/pulse to about 100 mW/pulse.

The wavelength at which the ultra-short pulse laser operates can also vary, for example, from about 100 nm to about 1000 nm For example, the ultra-short pulse laser can operate at a wavelength of about 100 nm, about 250 nm, about 500 nm, about 750 nm, about 1000 nm, or a range between any two of these values. In some embodiments, the ultra-short pulse laser operates at a wavelength range of about 100 nm to about 1000 nm

Apparatus 100 may include a computer configured to control the ultra-short pulse laser. For example, the computer can be adapted to control the movement of the laser beam relative to the surface of the metal substrate. In some embodiments, the computer may be directly coupled to the laser. In some embodiments, the computer may be wirelessly coupled to the laser.

Apparatus 100 may include at least one optical component. Any known optical component may be used, including but not limited to, optical lens 160. The optical lens can, in some embodiments, be a magnifier.

In some embodiments, the laser beam 170 may pass through the at least one optical component, such as the optical lens, prior to irradiating the metal substrate. As a non-limiting example, the optical lens may be positioned between the ultra-short pulse laser (for example ultra-short pulse laser 110) and the metal substrate (for example metal substrate 140). In some embodiments, the apparatus may include one or more minors. The mirror(s) may, in some embodiments, be used to reflect the laser beam (for example laser beam 170) from the laser before the laser beam contacts the metal substrate.

In some embodiments, housing 150 can include an optical port configured to allow irradiation of the metal substrate by the laser beam. The optical port can be of any size sufficient to allow the laser beam to irradiate the metal substrate. For example, the width of the optical port can be about 1 μm to about 150 μm. The width of the optical port can be, for example about 1 μm, about 10 μm, about 30 μm, about 60 μm, about 80 μm, about 100 jam, about 120 jam, about 150 μm, or a range between any two of these values. In some embodiments, the width of the optical port may be about 80 μm to about 100 μm.

Housing 150 can be configured to accommodate a metal substrate and carbon dioxide 130. The carbon dioxide 130 may be solid carbon dioxide, gaseous carbon dioxide or both. Housing 150 may be of any size or shape. A mixture that includes the metal substrate and the carbon dioxide 130 may partially, substantially, or entirely fill housing 150. The housing 150 may be made of any material suitable for accommodating a metal substrate and the carbon dioxide.

In some embodiments, apparatus 100 may include a support structure configured to secure the laser relative to the housing. In some embodiments, the support structure can aid in aligning the laser beam with the optical port of the housing. In some embodiments, the laser beam can be positioned such that the beam passes through the optical port of the housing to irradiate the metal substrate in the presence of carbon dioxide. In some embodiments, the support structure can be configured to allow movement of the laser beam relative to the metal substrate in the housing. In some embodiments, a computer may be adapted to control the movement of the laser beam relative to the metal substrate. The computer may be directly connected or wirelessly connected to the support structure to control the relative movement. As a non-limiting example, the computer may control the movement of the support structure, which may move the metal substrate relative to the laser beam.

The carbon dioxide may be in solid phase (as depicted by carbon dioxide 130 in FIG. 1), in gas phase, or a combination thereof. The metal substrate 140 may be partially surrounded, substantially surrounded, or entirely surrounded by carbon dioxide (for example, carbon dioxide gas). In some embodiments, the metal substrate may be partially surrounded by dry ice and partially surrounded by carbon dioxide gas.

The amount of carbon dioxide and the amount of the metal substrate that can be used are not particularly limited. In some embodiments, the ratio of the carbon dioxide to the metal substrate, by weight or by volume, may not be limited to specific ratios.

The amount of carbon dioxide relative to the amount of metal substrate can be determined through trial and error. For example, if it is observed that during the irradiation of the laser beam on the metal substrate that the amount of graphene formed had not increased with time, more carbon dioxide may be added.

The metal substrate 140 can include, but is not limited to, zinc, aluminum, magnesium, or a combination thereof. Other alkaline, alkaline earth metals, and transition metals may also be used.

The metal substrate can be in any shape or form. Non-limiting examples of the metal substrate include sheets of metal, powdered or granular metal, coils of metal, ribbons of metal, and the like. In some embodiments, the metal substrate may have multiple sides. In some embodiments, the metal substrate may be a three dimensional rectangle. In some embodiments, the metal substrate may be a thin sheet. In some embodiments, the metal substrate may be rigid. In some embodiments, the metal substrate may be flexible. The metal substrate can be porous or solid.

The size of the metal substrate is also not particularly limited. For example, the size of the metal substrate can be selected so that the metal substrate can fit within appropriate experimental apparatuses. For example, the metal substrate can be about 1 mm to about 1 meter in length, about 1 mm to about 1 meter in width, and/or about 1 mm to about 1 meter in height. In some embodiments, the metal substrate can be about 1 mm, about 5 mm, about 1 cm, about 5 cm, about 10 cm, about 50 cm, about 1 meter, or longer in length, or a length between any of these values. In some embodiments, the metal substrate can be about 1 mm, about 5 mm, about 1 cm, about 5 cm, about 10 cm, about 50 cm, about 1 meter, or longer in width, or a width between any of these values. In some embodiments, the metal substrate can be about 1 mm, about 5 mm, about 1 cm, about 5 cm, about 10 cm, about 50 cm, about 1 meter, or longer in height, or a height between any of these values. In some embodiments, the metal substrate can be several decimeters in length, several decimeters in width, and/or several decimeters in height.

In some embodiments, the apparatus may include a means for isolating the patterned graphene. The patterned graphene may be isolated from the metal substrate according to methods known in the art and appropriate means for carrying out such methods can be used. For example, the patterned graphene can be isolated from the metal substrate by transferring the patterned graphene from the surface of the metal substrate to another support surface. The transfer can be performed using any suitable methods known in the art including etching the metal substrate so that the patterned graphene is isolated from the surface of the metal substrate.

### Methods for Producing a Patterned Graphene

Some embodiments disclosed herein relate to methods of producing patterned graphene. The disclosed methods can include irradiating at least one focal point on a surface of a metal substrate with a laser beam in the presence of carbon dioxide, wherein the laser beam is generated by an ultra-short pulse laser, and causing the laser beam to move relative to the surface of the metal substrate such that the at least one focal point is displaced along a pattern on the surface, thereby producing a patterned graphene.

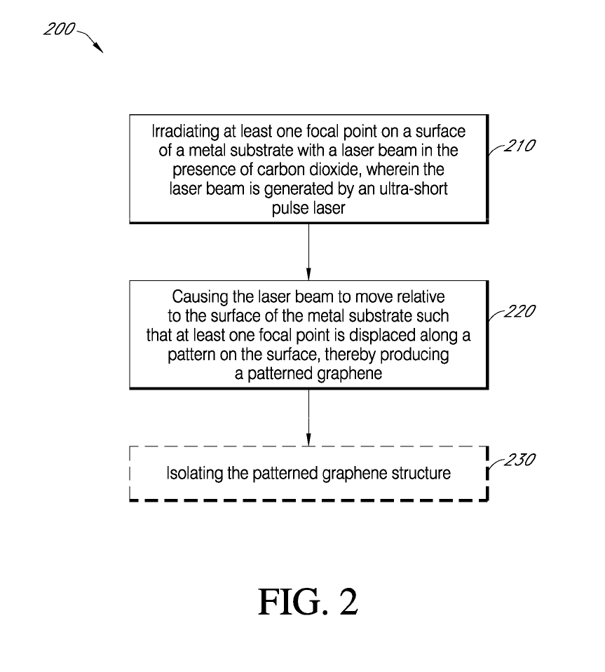

FIG. 2 is a flow diagram illustrating one non-limiting example of method of producing patterned graphene in accordance with the present disclosure. As illustrated in FIG. 2, method 200 can include one or more functions, operations, or actions as illustrated by one or more of operations 210-230.

Method 200 can begin at operation 210, “Irradiating at least one focal point on a surface of a metal substrate with a laser beam in the presence of carbon dioxide, wherein the laser beam is generated by an ultra-short pulse laser.” Operation 210 can be followed by operation 220, “Causing the laser beam to move relative to the surface of the metal substrate such that the at least one focal point is displaced along a pattern on the surface, thereby producing a patterned graphene.” Operation 220 can be followed by optional operation 230, “Isolating the patterned graphene.”

In FIG. 2, operations 210-230 are illustrated as being performed sequentially with operation 210 first and operation 230 last. It will be appreciated however that these operations can be reordered, combined, and/or divided into additional or different operations as appropriate to suit particular embodiments. For example, additional operations can be added before, during or after one or more of operations 210-230. In some embodiments, one or more of the operations can be performed at about the same time.

At operation 210, “Irradiating at least one focal point on a surface of a metal substrate with a laser beam in the presence of carbon dioxide, wherein the laser beam is generated by an ultra-short pulse laser,” the laser beam may contact at least one focal point on the surface of the metal substrate. The size of the at least one focal point may vary. For example, the diameter of the at least one focal point can be about 1 μm to about 150 μm. The diameter of the at least one focal point can be, for example about 1 μm, about 10 μm, about 30 μm, about 60 μm, about 80 μm, about 100 μm, about 120 μm, about 150 μm, or a range between any two of these values. In some embodiments, the diameter of the at least one focal point can be about 80 μm to about 100 μm. The at least one focal point may be on any surface of the metal substrate. In some embodiments, the at least one focal may be on one surface of the metal substrate. In some embodiments, the at least one focal point may be on two or more surfaces of the metal substrate. In some embodiments, the at least one focal point may be on one corner of a surface of the metal substrate.

Operation 210 can include irradiating at least one focal point on the metal substrate with the laser beam for a period of time. The period of time for which the metal substrate isirradiated can vary, for example, depending on the scanning rate of the laser beam, the power of the laser beam, and/or the size of the resultant patterned graphene. The metal substrate can be irradiated for at least about 2 seconds. In some embodiments, the metal substrate can be irradiated with the laser beam for at least about 5 seconds, at least about 20 seconds, at least about 30 seconds, at least about 40 seconds, at least about 1 minute, at least about 5 minutes, at least about 10 minutes, at least about 15 minutes, at least about 30 minutes, at least about 45 minutes, at least about 60 minutes, at least about 120 minutes, or longer, or any time between any of these values.

The ultra-short pulse lasers can include various lasers, for example, attosecond lasers, femtosecond lasers, excimer lasers, nanolasers, and the like, or a combination thereof. In some embodiments, the ultra-short pulse laser can be an attosecond laser, a femtosecond laser, an excimer laser, or a nanolaser. The power at which the ultra-short pulse laser operates can vary, for example, at about 0.001 mW/pulse to about 250 mW/pulse. In some embodiments, the ultra-short pulse laser may operate at a power of about 0.01 mW/pulse to about 150 mW/pulse, about 0.5 mW/pulse to about 100 mW/pulse, about 1 mW/pulse to about 75 mW/pulse, or a power within any of these ranges (including endpoints). In some embodiments, the laser beam ultra-short pulse laser may operate at a power of at least about 0.001 mW/pulse, at least about 0.1 mW/pulse, at least about 0.5 mW/pulse, at least about 0.8 mW/pulse, at least about 1 mW/pulse, or a power between any of these values. In some embodiments, the laser beam ultra-short pulse laser may operate at a power of less than about 150 mW/pulse, less than about 140 mW/pulse, less than about 130 mW/pulse, less than about 120 mW/pulse, less than about 110 mW/pulse, or a power between any of these values. In some embodiments, the ultra-short pulse laser may operate at a power of about 0.5 mW/pulse to about 100 mW/pulse.

The wavelength at which the ultra-short pulse laser operates can also vary, for example, from about 100 nm to about 1000 nm For example, the ultra-short pulse laser can operate at a wavelength of about 100 nm, about 250 nm, about 500 nm, about 750 nm, about 1000 nm, or a range between any two of these values.

In some embodiments, the carbon dioxide can be solid, in gas phase, or a combination thereof. For example, the carbon dioxide can be dry ice. The metal substrate can be partially surrounded, substantially surrounded, or entirely surrounded by carbon dioxide. In some embodiments, the metal substrate may be partially surrounded by carbon dioxide. In some embodiments, the metal substrate and carbon dioxide may be sequentially combined. In some embodiments, the metal substrate and carbon dioxide may be combined at about the same time.

The amount of carbon dioxide and amount of the metal substrate are not particularly limited. For example, the ratio of carbon dioxide to the metal substrate is not particularly limited.

The metal substrate can include, but is not limited to, zinc, aluminum, magnesium, or a combination thereof. Other alkaline, alkaline earth metals, and transition metals may also be used. The metal substrate can be in any shape or form. Non-limiting examples of the metal substrate include sheets of metal, powdered or granular metal, coils of metal, ribbons of metal, and the like. In some embodiments, the metal may have multiple sides. In some embodiments, the metal substrate may be a three dimensional rectangle. In some embodiments, the metal substrate may be a thin sheet. In some embodiments, the metal substrate may be rigid. In some embodiments, the metal substrate may be flexible. The metal substrate can be porous or solid.

The size of the metal substrate is also not particularly limited. For example, the metal substrate can range in size from several decimeters in length, several decimeters in width, and several decimeters in height, provided that the metal substrate can fit within appropriate experimental apparatuses. For example, the metal substrate can be selected so that the metal substrate can fit within appropriate experimental apparatuses. For example, the metal substrate can be about 1 mm to about 1 meter in length, about 1 mm to about 1 meter in width, and/or about 1 mm to about 1 meter in height. In some embodiments, the metal substrate can be about 1 mm, about 5 mm, about 1 cm, about 5 cm, about 10 cm, about 50 cm, about 1 meter, or longer in length, or a length between any of these values. In some embodiments, the metal substrate can be about 1 mm, about 5 mm, about 1 cm, about 5 cm, about 10 cm, about 50 cm, about 1 meter, or longer in width, or a width between any of these values. In some embodiments, the metal substrate can be about 1 mm, about 5 mm, about 1 cm, about 5 cm, about 10 cm, about 50 cm, about 1 meter, or longer in height, or a height between any of these values. In some embodiments, the metal substrate can be several millimeters in length, several millimeters in width, and/or several millimeters in height. In some embodiments, the metal substrate can be several centimeters in length, several centimeters in width, and/or several centimeters in height.

In some embodiments, the laser may pass through an optical component prior to irradiating the focal point. The optical component may be any known in the art, such as an optical lens. In such embodiments, the laser beam, after passing through the optical component, may irradiate the metal substrate.

Operation 220, “Causing the laser beam to move relative to the surface of the metal substrate such that the at least one focal point is displaced along a pattern on the surface, thereby producing a patterned graphene,” can include producing a desired pattern on the surface of the metal substrate. Any desired pattern may be produced. In some embodiments, operation 220 can include producing a patterned graphene. The patterned graphene can be produced on a portion of or entire surface of the metal substrate. For example, the patterned graphene can be produced on about 10%, about 30%, about 40%, about 50%, about 60%, about 70%, about 80%, about 90%, about 95%, about 99%, about 100% or a range between any two of these values of the surface of the metal substrate. In some embodiments, the patterned graphene may be produced on about 60% to about 100% of the surface of the metal substrate.

At operation 220, the movement of the laser beam relative to the surface of the metal substrate may be controlled by a computer. In some embodiments, controlling the relative moment may lead to the formation of various patterns and/or the production of patterned graphene.

In some embodiments, the movement of the laser beam relative to the surface of the metal substrate may include moving the laser beam. The ultra-short pulse laser and/or laser beam may be configured to be operated by a computer. The computer can be directly coupled to the laser device, or can control the laser device via wireless means.

In some embodiments, the movement of the laser beam relative to the surface of the metal substrate may include moving the metal substrate. In some embodiments, the metal substrate can be moved by computer. For example, the computer may be directly coupled or wirelessly coupled to a housing configured to accommodate a metal substrate and carbon dioxide. In some embodiments, the computer can control the movement of the housing and thus the movement of the metal substrate.

Operation 220 may include the laser beam moving relative to the metal substrate at a scanning speed. The scanning speed of the laser beam is not particularly limited. For example, the laser beam can move relative to the metal substrate at a scanning speed of at least about 0.0001 mm/s In some embodiments, the laser beam can move relative to the metal substrate at a scanning speed of about 0.0001 mm/s to about 20 mm/s, about 0.001 to about 15 mm/s, about 0.005 mm/s to about 10 mm/s, or about 0.01 to about 8 mm/s, or a speed within any of these ranges (including endpoints). In some embodiments, the laser beam can move relative to the metal substrate at a scanning speed of at least about 0.0001 mm/s, at least about 0.001 mm/s, at least about 0.005 mm/s, at least about 0.05 mm/s, or at least about 0.01 mm/s, or a speed between any of these values. In some embodiments, the scanning speed can be less than about 20 mm/s, less than about 16 mm/s, less than about 12 mm/s, less than about 10 mm/s, or less than about 8 mm/s, or a speed between any of these values.

Optionally, Operation 220 may be followed by operation 230, “Isolating the patterned graphene.” Operation 230 can include any known methods for suitable for isolating patterned graphene from a metal substrate. For example, the patterned graphene can be isolated from the metal substrate by transferring the patterned graphene from the surface of the metal substrate to another support surface. The transfer can be performed using any suitable methods known in the art including etching so the metal substrate so that the patterned graphene is isolated from the surface of the metal substrate.

### EXAMPLES

Additional embodiments are disclosed in further detail in the following examples, which are not in any way intended to limit the scope of the claims.

### Example 1

### Production of Patterned Graphene From Zinc

30 g of zinc metal sheet (1.0 cm by 1.0 cm) was combined with 100 g of dry ice and placed in a chamber having an opening sufficient for a laser beam to pass through. A femtosecond laser (ran at the power of 1 mW/pulse, scanning speed of 1 mm/s, wavelength at 800 nm, and frequency of 1000 Hz) was directed at the metal sheets for 10 minutes, thereby producing patterned graphene that covered approximately 30% of the surface area of the zinc metal sheet.

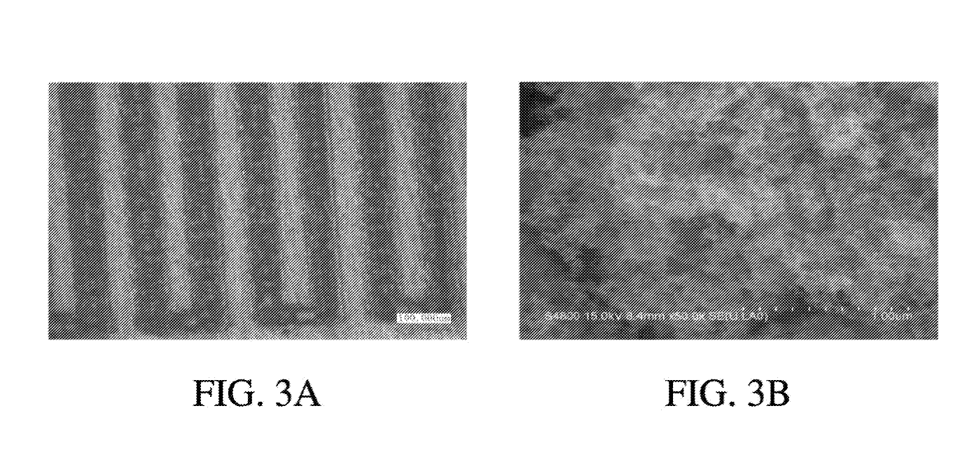

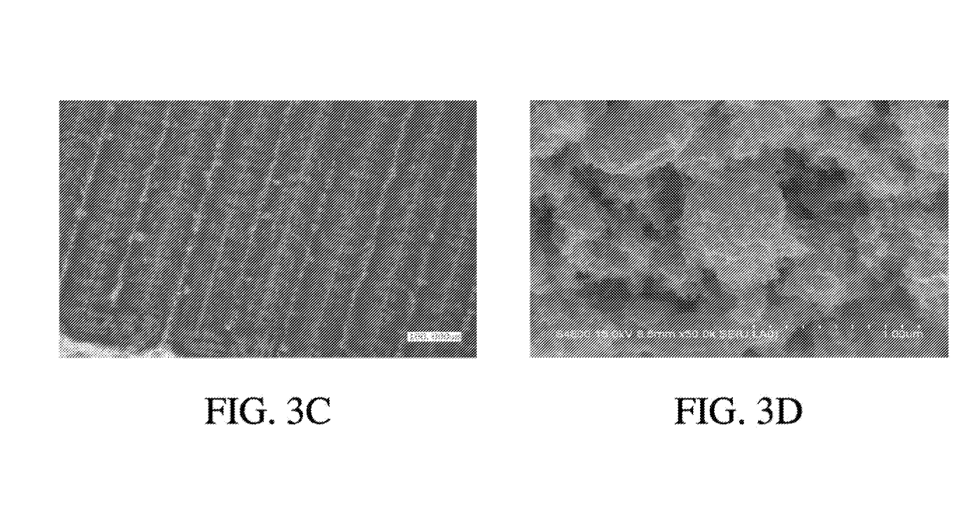

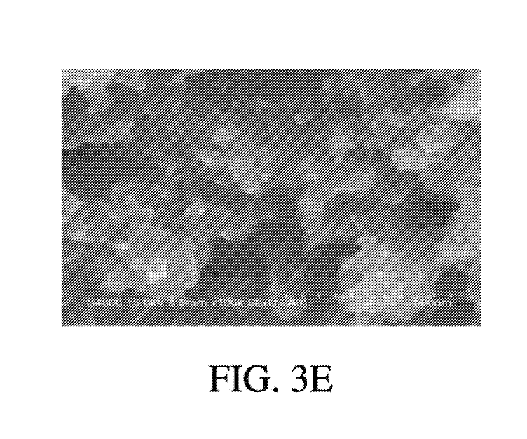

The resultant graphene was observed via an optical microscope and by scanning electron microscope (SEM) and compared to graphene prepared on a zinc sheet by scanning a laser in air. For comparison, the laser scanning process was also carried out in air (in which no dry ice was added), and FIGS. 3A and 3B depict an optical microphotograph and SEM, respectively, of the resulting pattern on the zinc metal sheet. No graphene was formed when the laser scanning process was carried out in air and in the absence of dry ice.

FIG. 3C depicts an optical microscope image of patterned graphene prepared from zinc and irradiated with the above-described laser beam in the presence of carbon dioxide. FIGS. 3D and 3E are SEM images (at 1.00 μm and 500 nm, respectively), of patterned graphene prepared from zinc and irradiated with the above-described laser beam in the presence of carbon dioxide. As shown by the figures, the product synthesized in the presence of carbon dioxide according to the disclosed method is patterned graphene.

### Example 2

### Production of Patterned Graphene From Zinc

Graphene was synthesized according to the procedure described in Example 1 except that 50 g of aluminum sheets (1.5 cm by 1.5 cm) was used as the metal substrate.

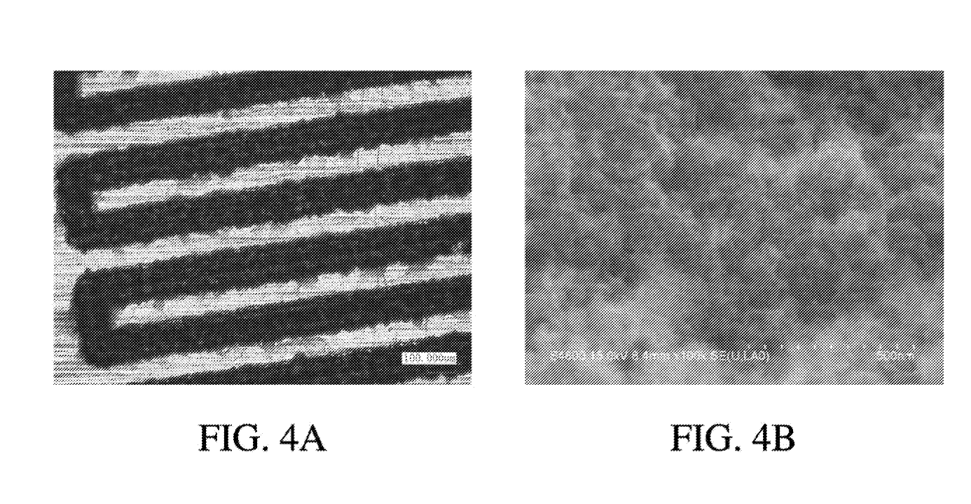

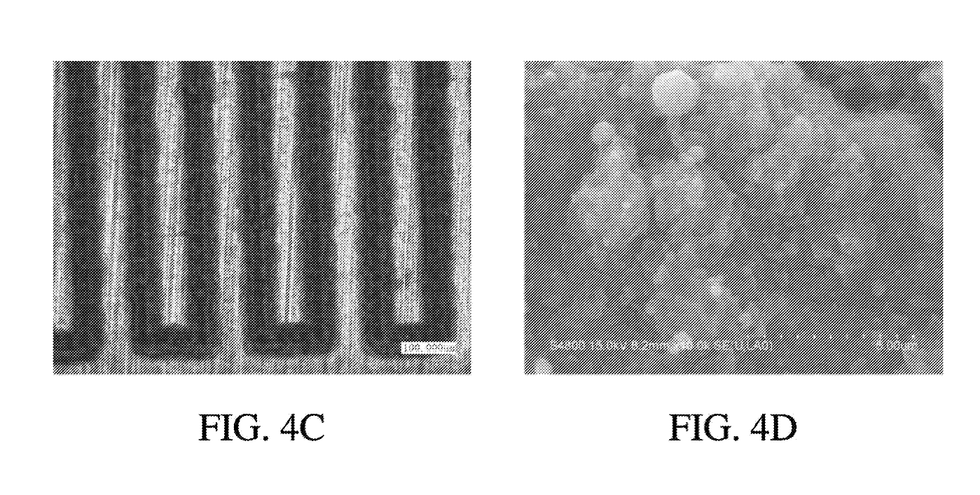

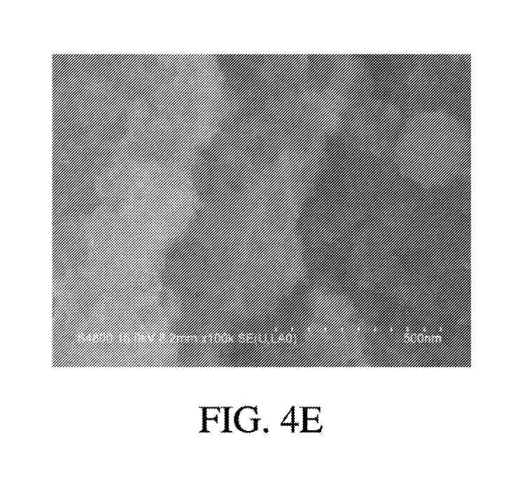

FIGS. 4A and 4B show an optical microscope image and a SEM image, respectively, of the pattern synthesized on the surface of the aluminum sheet by scanning the laser in air and in the absence of dry ice; no graphene was produced via this method. FIGS. 4C, 4D, and 4E show an optical microscope image and SEM images (at 5.00 μm and 500 nm, respectively), respectively, of patterned graphene synthesized from aluminum and irradiated with the above-described laser beam in the presence of carbon dioxide. As shown by the figures, the product synthesized in the presence of carbon dioxide according to the disclosed method is patterned graphene.

### Example 3

### Production of Patterned Graphene From Magnesium

Graphene was synthesized according to the procedure described in

Example 1 except that 15 g of magnesium sheets (1.0 cm by 1.0 cm) was used as the metal substrate.

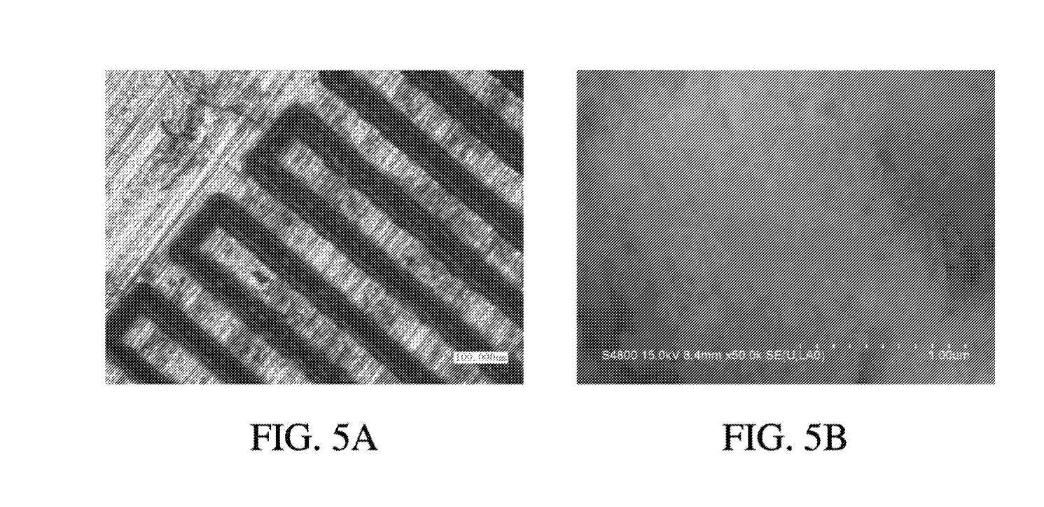

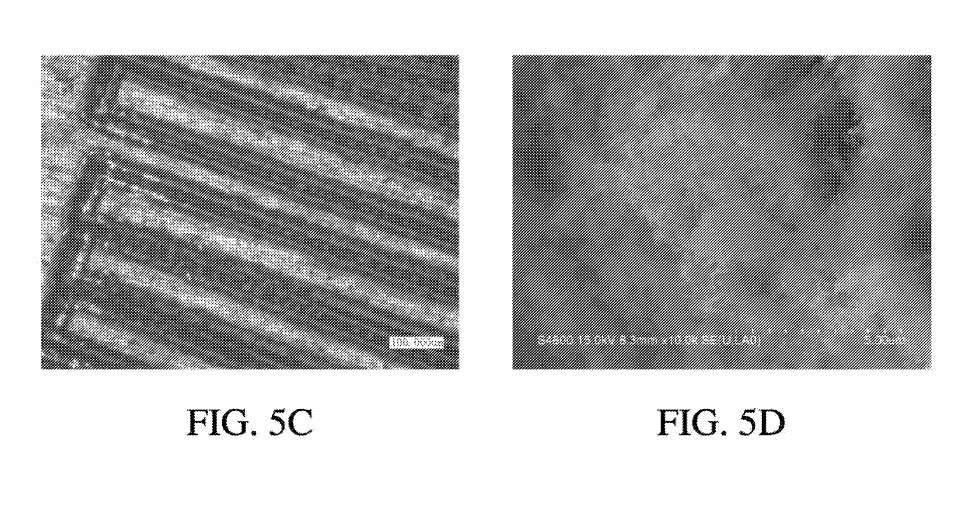

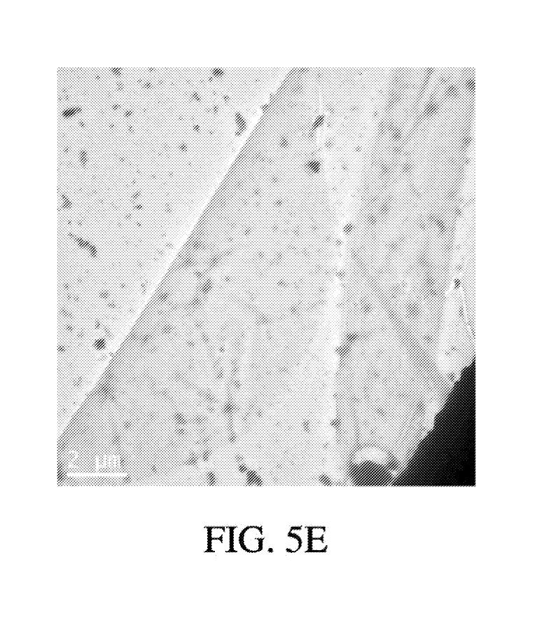

FIGS. 5A and 5B are an optical microscope image and a SEM image, respectively, of the pattern synthesized on the surface of the aluminum sheet by scanning the laser in air and in the absence of dry ice. As shown in FIGS. 5A and 5B, no graphene was produced via this method in the absence of dry ice. FIGS. 5C, 5D and 5E depict an optical microscope image, SEM image (at 5.00 μm), and a transmission electron microscopy (TEM) image, respectively, of patterned graphene synthesized from magnesium and irradiated with the above-described laser beam in the presence of carbon dioxide. As shown by the figures, the product synthesized in the presence of carbon dioxide according to the disclosed method is patterned graphene.

Examples 1 to 3 above demonstrate that both graphene and the patterns on the graphene, can be formed simultaneously by exposing a metal substrate to a laser beam in the presence of carbon dioxide. Therefore, problems associated with separate forming of graphene (for example, by chemical vapor deposition methods or expitaxial growth methods), followed by forming of patterns on the graphene as described above, can be avoided or at least ameliorated.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (for example, “ a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (for example, “ a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible sub-ranges and combinations of sub-ranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into sub-ranges as discussed above. Finally, as will be understood by one skilled in the art, a range includes each individual member. Thus, for example, a group having 1-3 articles refers to groups having 1, 2, or 3 articles. Similarly, a group having 1-5 articles refers to groups having 1, 2, 3, 4, or 5 articles, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

1. A method for producing a patterned graphene, the method comprising:
irradiating at least one focal point on a surface of a metal substrate with a laser beam in the presence of carbon dioxide, wherein the laser beam is generated by an ultra-short pulse laser;
and causing the laser beam to move relative to the surface of the metal substrate such that the at least one focal point is displaced along a pattern on the surface, thereby producing the patterned graphene.

2. The method of claim 1, further comprising isolating the patterned graphene.

3. The method of claim 1, wherein the laser beam passes through an optical component prior to irradiating the focal point.

4. The method of claim 3, wherein the optical component comprises an optical lens.

5. The method of claim 1, wherein the ultra-short pulse laser comprises an attosecond laser, a femtosecond laser, an excimer laser, or a nano-laser.

6. The method of claim 1, wherein causing the laser beam to move relative to the surface of the metal substrate comprises moving the laser beam.

7. The method of claim 1, wherein causing the laser beam to move relative to the surface of the metal substrate comprises moving the metal substrate.

8. The method of claim 1, wherein causing the laser beam to move relative to the surface of the metal substrate comprises controlling the relative movement by a computer.

9. The method of claim 1, wherein the ultra-short pulse laser operates at a power of about 0.5 mW/pulse to about 100 mW/pulse.

10. The method of claim 1, wherein the ultra-short pulse laser operates at a wavelength of about 100 nm to about 1000 nm.

11. The method of claim 1, wherein the laser beam moves relative to the metal substrate at a scanning speed of about 0.005 mm/s to about 10 mm/s.

12. The method of claim 1, wherein the metal substrate comprises zinc, aluminum, magnesium, or a combination thereof.

13. The method of claim 1, wherein the carbon dioxide is solid carbon dioxide, gaseous carbon dioxide, or both.

14. An apparatus for producing a patterned graphene, the apparatus comprising:
an ultra-short pulse laser configured to produce a laser beam; and
a housing configured to accommodate a metal substrate and carbon dioxide, wherein the housing comprises an optical port configured to allow irradiation of at least one focal point on a surface of the metal substrate by the laser beam.

15. The apparatus of claim 14, wherein the ultra-short pulse laser comprises an attosecond laser, a femtosecond laser, an excimer laser, or a nano-laser.

16. The apparatus of claim 14, further comprising a lens positioned between the ultra-short pulse laser and the metal substrate.

17. The apparatus of claim 14, further comprising a support structure that secures the laser relative to the housing.

18. The apparatus of claim 17, wherein the support is configured to allow movement of the laser beam relative to the metal substrate in the housing.

19. The apparatus of claim 14, further comprising a computer coupled to the ultra-short pulse laser and configured to control the ultra-short pulse laser.

20-21. (canceled)

22. The apparatus of claim 14, wherein the carbon dioxide is at least one of solid carbon dioxide or gaseous carbon dioxide.
